(19) United States
(12) Patent Application Publication
(10) Pub. No.: US 2025/0320624 A1
(43) Pub. Date: Oct. 16, 2025

(54) CRYSTAL PREPARATION DEVICES AND CRYSTAL PREPARATION METHODS

(71) Applicant: MEISHAN BOYA ADVANCED MATERIALS CO., LTD., Meishan (CN)

(72) Inventors: Yu WANG, Meishan (CN); Weiming GUAN, Meishan (CN)

(73) Assignee: MEISHAN BOYA ADVANCED MATERIALS CO., LTD., Meishan (CN)

(21) Appl. No.: 19/249,974

(22) Filed: Jun. 25, 2025

Related U.S. Application Data
(63) Continuation of application No. PCT/CN2022/144331, filed on Dec. 30, 2022.

(51) Int. Cl. C30B 13/24; C30B 13/14; C30B 13/28

(52) U.S. Cl. CPC C30B 13/24; C30B 13/14; C30B 13/28

(57) ABSTRACT

Embodiments of the present disclosure provide a crystal preparation device and a crystal preparation method. The crystal preparation device comprises a cavity configured to accommodate raw material; a laser heating assembly configured to heat the raw material; and a control assembly configured to adjust a heating parameter of the laser heating assembly in real-time during a crystal growth process.

### CROSS REFERENCE TO RELATED APPLICATIONS

This application is a continuation of international application No. PCT/CN2022/144331, filed on Dec. 30, 2022, the entire contents of which are incorporated herein by reference.

### TECHNICAL FIELD

The present disclosure relates to the field of crystal preparation technology, and in particular, to a crystal preparation device and a crystal preparation method.

### BACKGROUND

With the development of science and technology, the quality requirements for crystals have become increasingly stringent in certain high-end devices and scientific research applications. During the crystal growth process, factors such as the temperature field and temperature gradient directly affect the quality of the crystal. Therefore, it is necessary to provide an improved crystal preparation device and crystal preparation method to facilitate real-time and precise control of the temperature field, temperature gradient, and other parameters during the crystal growth process.

### SUMMARY

One of the embodiments of the present disclosure provides a crystal preparation device. The crystal preparation device comprises a cavity configured to accommodate raw material; a laser heating assembly configured to heat the raw material; and a control assembly configured to adjust a heating parameter of the laser heating assembly in real-time during a crystal growth process.

In some embodiments, the cavity includes a cooling structure, and the cooling structure includes an inlet, an outlet, and a cooling channel.

In some embodiments, the laser heating assembly includes at least two laser-emitting units installed on a furnace cover above the cavity.

In some embodiments, the at least two laser-emitting units are arranged along a circumferential direction of the furnace cover.

In some embodiments, the at least two laser-emitting units form at least one ring-like shape along the circumferential direction of the furnace cover.

In some embodiments, a difference between a radius of an outermost ring-like shape of the at least one ring-like shape and a radius of the cavity is in a range of 50 mm to 500 mm.

In some embodiments, a radius of an innermost ring-like shape of the at least one ring-like shape is in a range of 25 mm to 300 mm.

In some embodiments, the at least two laser-emitting units form at least two ring-like shapes along the circumferential direction of the furnace cover, and a radius difference between adjacent ring-like shapes of the at least two ring-like shapes is in a range of 5 mm to 200 mm.

In some embodiments, the heating parameter of the laser heating assembly includes at least one of an operating power of the laser heating assembly, a shape of a laser beam, or a size of the laser beam.

In some embodiments, the control assembly is configured to adjust a temperature gradient in real-time during the crystal growth process by controlling the heating parameter of the laser heating assembly.

In some embodiments, the crystal preparation device further comprises a temperature-measuring assembly configured to measure temperature information related to the raw material or the cavity.

In some embodiments, the control assembly is configured to adjust the heating parameter of the laser heating assembly in real-time based on the temperature information.

In some embodiments, the control assembly is configured to perform simulation modeling based on the temperature information and adjust the heating parameter of the laser heating assembly in real-time based on a simulation result.

In some embodiments, the crystal preparation device further comprises a feeding assembly configured to feed material in real-time during the crystal growth process.

One of the embodiments of the present disclosure further provides a crystal preparation method. The crystal preparation method comprises placing raw material in a cavity; heating the raw material by a laser heating assembly to melt a portion of the raw material into a raw material melt; and performing a crystal growth process based on the raw material melt, wherein a heating parameter of the laser heating assembly is adjusted in real-time during the crystal growth process.

In some embodiments, the heating parameter of the laser heating assembly include at least one of an operating power of the laser heating assembly, a shape of a laser beam, or a size of the laser beam.

In some embodiments, the crystal preparation method further comprises adjusting a temperature gradient in real-time during the crystal growth process by adjusting the heating parameter of the laser heating assembly.

In some embodiments, the temperature gradient includes a radial temperature gradient, and the radial temperature gradient includes a first temperature gradient and a second temperature gradient. The first temperature gradient is a temperature gradient along a direction from a ring-like heating zone formed by the laser heating assembly to a crystal growth center point, the first temperature gradient being a negative temperature gradient; and the second temperature gradient is a temperature gradient along a direction from the ring-like heating zone to an inner wall of the cavity, the second temperature gradient being a negative temperature gradient.

In some embodiments, the crystal preparation method further comprises adjusting the heating parameter of the laser heating assembly in real-time based on temperature information related to the raw material or the cavity.

In some embodiments, the crystal preparation method further comprises performing simulation modeling based on temperature information related to the raw material or the cavity, and adjusting the heating parameter of the laser heating assembly in real-time based on a simulation result.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, wherein:

FIG. 1 is a schematic diagram illustrating an exemplary structure of a crystal preparation device according to some embodiments of the present disclosure;

FIG. 2 is a schematic diagram illustrating an exemplary structure of a cavity according to some embodiments of the present disclosure;

FIG. 3 is a schematic diagram illustrating an exemplary structure of a cavity and an insulation assembly according to some embodiments of the present disclosure;

FIG. 4A is a schematic diagram illustrating a top view of a furnace cover according to some embodiments of the present disclosure;

FIG. 4B is a schematic diagram illustrating a top view of a furnace cover according to some other embodiments of the present disclosure;

FIG. 5 is a schematic diagram illustrating an exemplary installation structure of at least two laser-emitting units according to some embodiments of the present disclosure;

FIG. 6 is a flowchart illustrating a process of a crystal preparation method according to some embodiments of the present disclosure;

FIG. 7 is a schematic diagram illustrating exemplary temperature field distribution inside a cavity according to some embodiments of the present disclosure;

FIG. 8 is a diagram illustrating a crystal prepared according to Embodiment 1 of the present disclosure; and

FIG. 9A and FIG. 9B are diagrams illustrating crystals prepared according to Embodiment 2 of the present disclosure.

Markings in the figures denote: 100, crystal preparation device; 110, furnace; 111, furnace body; 112, furnace cover; 1121, first through-hole; 1122, laser input window; 11221, laser input window top cover; 11222, laser input window column; 11223, connecting member; 1123, cooling pathway; 1124, pathway inlet; 1125, pathway outlet; 1126, pathway; 113, bottom plate; 120, lifting assembly; 121, sealing sleeve; 130, moving assembly; 140, furnace rack; 150, shifting assembly; 151, shifting rod; 152, driving component; 200, cavity; 210, cooling structure; 211, inlet; 212, outlet; 213, cooling channel; 220, inner cavity body; 230, outer cavity body; 300, insulation assembly; 310, upper insulation component; 311, first gap, 312, at least two through-holes; 320, middle insulation component; 330, lower insulation component; 400, tray assembly; 410, tray through-hole; 500, at least two laser-emitting units.

### DETAILED DESCRIPTION

In order to more clearly illustrate the technical solutions of the embodiments of the present disclosure, the following will briefly introduce the accompanying drawings to be used in the description of the embodiments. Obviously, the accompanying drawings in the following description are only some examples or embodiments of the present disclosure, and a person of ordinary skill in the art can apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit,” and/or “module” as used herein are a way to distinguish between different components, elements, parts, sections, or assemblies at different levels. However, the terms may be replaced by other expressions if other expressions accomplish the same purpose.

As shown in the present disclosure and the claims, unless the context clearly suggests an exception, the words “a,” “an,” “one,” “one kind,” and/or “the” do not refer specifically to the singular, but may also include the plural. Generally, the terms “including” and “comprising” suggest only the inclusion of clearly identified operations and elements that do not constitute an exclusive list, and the method, system, or device may also include other operations or elements.

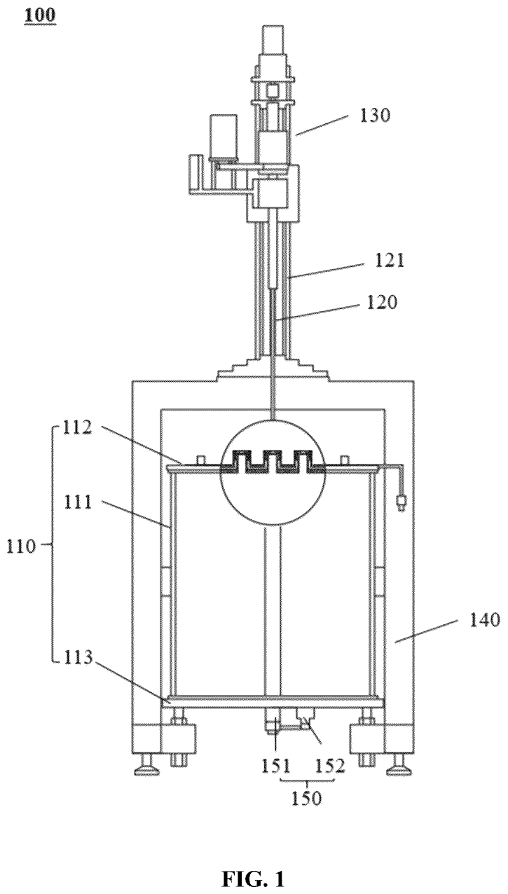

FIG. 1 is a schematic diagram illustrating an exemplary structure of a crystal preparation device according to some embodiments of the present disclosure. In some embodiments, a crystal preparation device 100 may be used to prepare crystals such as Yttrium Aluminum Garnet (YAG), Lithium Niobate (LN), Lithium Tantalate (LT), Lutetium Oxyorthosilicate (LSO), Lutetium-Yttrium Oxyorthosilicate (LYSO), Beta Barium Borate (BBO), Lithium Triborate (LBO), Yttrium Orthovanadate (YVO₄), and doped crystals thereof.

In some embodiments, as shown in FIG. 1, the crystal preparation device 100 may include a furnace 110, a cavity (not shown in the figure), a heating assembly (not shown in the figure), a lifting assembly 120, a moving assembly 130, and a control assembly (not shown in the figure).

The furnace 110 may be configured to accommodate at least a portion of assemblies (e.g., the cavity) of the crystal preparation device 100. In some embodiments, the shape of the furnace 110 may be a cylinder, a cube, a polygonal cylinder (e.g., a triangular prism, a pentagonal prism, a hexagonal prism), or the like. In some embodiments, the furnace 110 may be a hermetically sealed or non-hermetically sealed structure. In some embodiments, the material of the furnace 110 may include, but is not limited to, stainless steel or quartz.

In some embodiments, the furnace 110 may include a furnace body 111, a furnace cover 112, and a bottom plate 113. The furnace cover 112 may be provided on the top of the furnace body 111. The bottom plate 113 may be provided at the bottom of the furnace body 111. In some embodiments, the furnace cover 112 and/or the bottom plate 113 may or may not be sealed to an outer wall of the furnace body 111.

In some embodiments, an insulation cylinder (not shown in the figure) may be disposed inside the furnace 110. At least a portion of the insulation cylinder may be disposed inside the furnace 110. In some embodiments, an upper end of the insulation cylinder may be level with an upper surface of the furnace cover 112. In some embodiments, the upper end of the insulation cylinder may be higher than the upper surface of the furnace cover 112. In some embodiments, the shape of the insulation cylinder may be a cylinder, a cube, a polygonal cylinder (e.g., a triangular prism, a pentagonal prism, a hexagonal prism), or the like. In some embodiments, the material of the insulation cylinder may include quartz (silicon oxide), corundum (alumina), zirconia, graphite, carbon fiber, ceramics, or the like, or other high-temperature-resistant materials (e.g., rare-earth metal borides, carbides, nitrides, silicides, phosphides, and sulfides, or the like). For example, the insulation cylinder may be a quartz tube.

In some embodiments, an upper sealing cover may be provided at the upper end of the insulation cylinder. The upper sealing cover and the insulation cylinder may be connected hermetically (e.g., glued or snap-fit through a sealing ring). In some embodiments, the upper sealing cover and the furnace cover 112 may be configured as an integrated structure. In some embodiments, the upper sealing cover may be provided with an observation member, by which the interior of the insulation cylinder may be observed.

In some embodiments, a lower sealing cover may be provided at a bottom end of the insulation cylinder. The lower sealing cover and the insulation cylinder may be connected hermetically (e.g., glued or snap-fit through a sealing ring). In some embodiments, the bottom end of the insulation cylinder may not be provided with the lower sealing cover. For example, the bottom end of the insulation cylinder may be hermetically connected to the bottom plate 113.

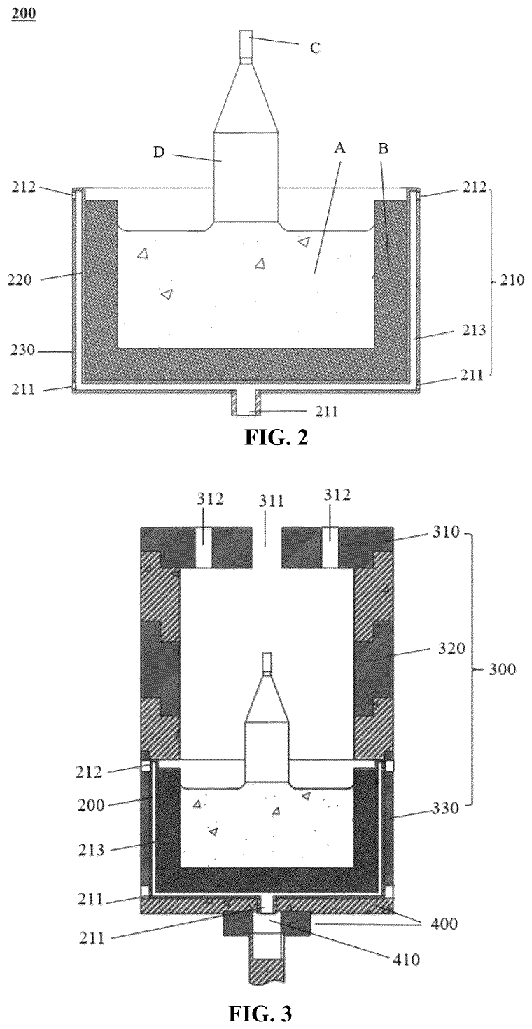

The cavity may be configured to accommodate raw material required for crystal growth. In some embodiments, the cavity may be located inside the furnace 110 (e.g., inside the insulation cylinder). In some embodiments, the cavity may include a cooling structure to reduce the temperature of the cavity to avoid contamination of the raw material (e.g., a raw material melt) due to volatilization of the cavity at high temperatures, thereby ensuring the quality of a grown crystal. Related descriptions of the cavity can be found elsewhere in the present disclosure (e.g., FIG. 2 and related description thereof) and will not be repeated here.

In some embodiments, the crystal preparation device 100 may further include an insulation assembly (not shown in the figure). In some embodiments, the insulation assembly may at least partially enclose the cavity. For example, the insulation assembly may be disposed inside the insulation cylinder and around the outer periphery of the cavity. Related descriptions of the insulation assembly can be found elsewhere in the present disclosure (e.g., FIG. 3 and related description thereof) and will not be repeated here.

The heating assembly may be configured to heat the raw material to provide heat (e.g., a temperature field) required for crystal preparation. In some embodiments, the heating assembly may include a laser heating assembly.

In some embodiments, the laser heating assembly may include at least two laser-emitting units for emitting lasers to provide a heat source. In some embodiments, the laser heating assembly may further include at least two laser shaping and collimating lenses for adjusting the shape and/or size of laser beams emitted by the at least two laser-emitting units. In some embodiments, the at least two laser shaping and collimating lenses correspond to the at least two laser-emitting units. For example, the at least two laser shaping and collimating lenses may be installed on paths where the laser beams emitted by the at least two laser-emitting units are located.

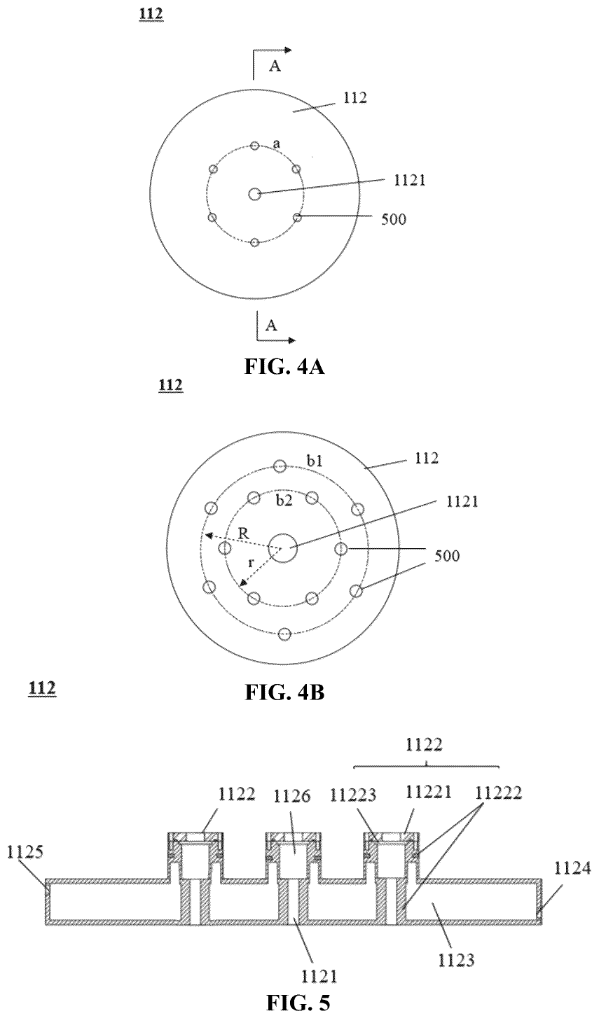

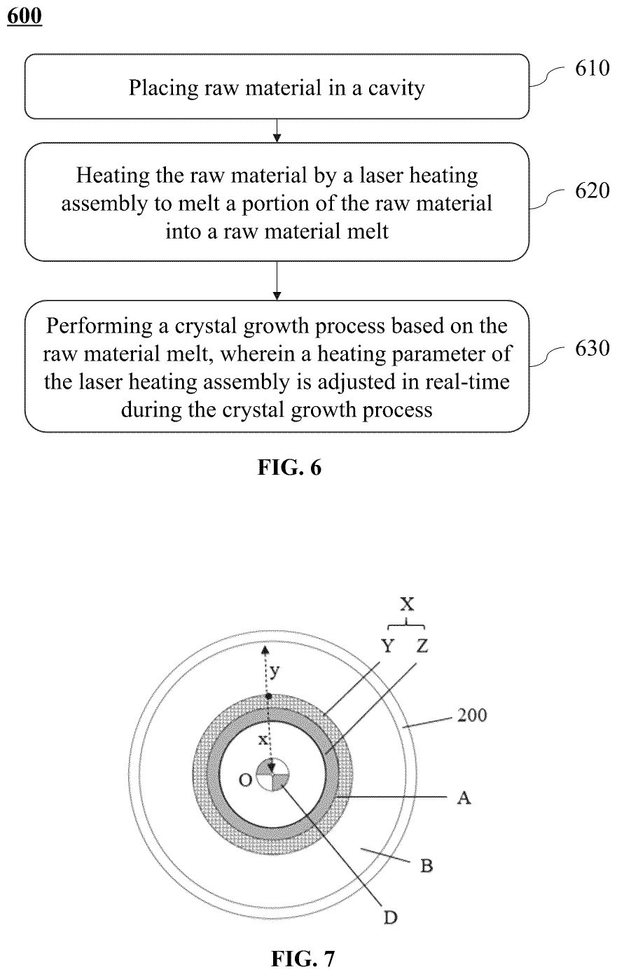

In some embodiments, the laser heating assembly may be installed on the furnace cover 112 above the cavity or the upper sealing cover. In some embodiments, laser output ports of the at least two laser-emitting units may correspond to the interior of the cavity to heat the raw material inside the cavity. The manner in which the at least two laser-emitting units are arranged on the furnace cover 112 above the cavity or upper sealing cover can be found elsewhere in the present disclosure (e.g., FIG. 4A, FIG. 4B, FIG. 5, and the descriptions thereof) and will not be repeated here.

The lifting assembly 120 may be configured to move up and down and/or rotate for crystal growth. The moving assembly 130 may be configured to drive the lifting assembly 120 to move up and down and/or rotate. In some embodiments, one end of the lifting assembly 120 may pass through through-holes in the upper sealing cover and the furnace cover 112 and move up and down and/or rotate, and another end of the lifting assembly and the moving assembly 130 may be operatively connected.

In some embodiments, the sealing sleeve 121 may be disposed around the exterior of the lifting assembly 120. One end of the sealing sleeve 121 may be in communication with the insulation cylinder through the through-hole in the upper sealing cover, or in communication with the furnace 110 through the through-hole in the furnace cover 112. Another end of the sealing sleeve 121 may be hermetically connected (e.g., welded, glued, or bolted) to the moving assembly 130. In some embodiments, the sealing sleeve 121 can keep the lifting assembly 120 in a hermetic environment. In some embodiments, the air pressure environment inside the sealing sleeve 121 may be the same as or different from the air pressure environment inside the insulation cylinder.

In some embodiments, the crystal preparation device 100 may further include a vacuum assembly configured to create a vacuum or a pressure environment lower than the standard atmospheric pressure inside the furnace body 110, the insulation cylinder, and/or the cavity. In some embodiments, the vacuum assembly may be connected to the insulation cylinder through the through-hole and a conduit in the upper sealing cover, or connected to the furnace 110 through the through-hole and a conduit in the furnace cover 112. In some embodiments, the vacuum assembly may include a power component (e.g., a mechanical pump) and a gas storage component (e.g., a gas storage bottle) configured to evacuate and introduce a gas (e.g., an inert gas), respectively.

In some embodiments, the crystal preparation device 100 may further include a furnace rack 140 for carrying assemblies such as the furnace 110. In some embodiments, the furnace rack 140 may be provided at the bottom of the furnace 110. In some embodiments, the furnace rack 140 and the furnace 110 may be integrally molded or may be fixedly connected (e.g., bolted, welded, hinged). In some embodiments, the furnace 110 may be placed directly on the furnace rack 140. In some embodiments, the furnace rack 140 may be a cubic or cylindrical steel rack structure. In some embodiments, legs of the furnace rack 140 may be round or square steel tubes. In some embodiments, the furnace rack 140 may also be of other reasonable construction known to those of skill in the art, which is not limited herein.

In some embodiments, the crystal preparation device 100 may further include a tray assembly (not shown in the figure) configured to support the cavity and the insulation assembly. In some embodiments, the tray assembly may be provided on the lower sealing cover or the bottom plate 113. In some embodiments, the material of the tray assembly may include quartz (silicon oxide), corundum (alumina), zirconia, graphite, carbon fiber, ceramics, etc., or other high-temperature-resistant materials such as borides, carbides, nitrides, silicides, phosphides, and sulfides of rare earth metals.

In some embodiments, the crystal preparation device 100 may further include a shifting assembly 150 configured to drive the cavity to move. In some embodiments, the shifting assembly 150 may include a shifting rod 151 and a driving component 152. In some embodiments, the shifting rod 151 and the cavity may be fixedly connected. In some embodiments, the driving component 152 may include, but is not limited to, a line drive mechanism, a hinge drive mechanism, a rack and pinion drive mechanism, a screw and nut drive mechanism, or the like. The driving component 152 is connected to the shifting rod 151, and the driving component 152 is configured to drive the cavity to move by driving the shifting rod 151 to move (e.g., move up and down).

In some embodiments, the control assembly may adjust a heating parameter of the heating assembly (e.g., the laser heating assembly) in real-time during a crystal growth process. In some embodiments, the control assembly may adjust a temperature gradient in real-time during the crystal growth process by controlling the heating parameter of the laser heating assembly. In some embodiments, the temperature gradient may include a radial temperature gradient and/or an axial temperature gradient. In some embodiments, the control assembly may adjust the heating parameter of the laser heating assembly in real-time to regulate the temperature at a specific position (e.g., at a specific raw material position inside the cavity, at a specific position within the melt, or at a solid-liquid interface between the melt and the raw material) during the crystal growth process, or to regulate an average temperature across a plurality of positions, a temperature variance across a plurality of positions, melt temperature distribution (e.g., a temperature distribution curve or a temperature distribution map), raw material temperature distribution, temperature distribution inside the cavity, etc., or any combination thereof.

In embodiments of the present disclosure, the temperature distribution may reflect the distribution of temperature in time and space. The temperature distribution, the temperature field, the temperature field distribution, and the temperature field information may be used interchangeably unless otherwise noted.

In some embodiments, the heating parameter of the laser heating assembly may include the shape, size, etc., of a laser beam or any combination thereof. In some embodiments, the heating parameter of the laser heating assembly may further include an operating power of the at least two laser-emitting units. A detailed description of the real-time adjustment of the temperature gradient, the temperature value at the specific position, the average temperature across a plurality of positions, the temperature variance across a plurality of positions, the melt temperature distribution, etc., during the crystal growth process by controlling the heating parameter of the laser heating assembly controlled by the control assembly can be found in the other parts of the present disclosure (e.g., FIG. 6 and the description thereof), and will not be repeated herein.

In some embodiments, the control assembly may include a central processing unit (CPU), an application-specific integrated circuit (ASIC), an application-specific instruction set processor (ASIP), an image processor (GPU), a physical operations processing unit (PPU), a digital signal processor (DSP), a field programmable gate array (FPGA), a programmable logic device (PLD), a controller, a microcontroller unit, a reduced instruction set computer (RISC), a microprocessor, etc. or any combination thereof.

In some embodiments, the crystal preparation device 100 may further include a temperature-measuring assembly (not shown in the figure). In some embodiments, the temperature-measuring assembly may include at least one temperature sensing component configured to measure temperature information related to the raw material or the cavity and send the measured temperature information to the control assembly. In some embodiments, the temperature sensing component may include, but is not limited to, an infrared pyrometer, a photoelectric pyrometer, a fiber optic radiation thermometer, a colorimetric thermometer, an ultrasonic thermometer, a microwave sensor, a thermocouple sensor, or the like, or any combination thereof. In some embodiments, the temperature information related to the raw material or the cavity may include, but is not limited to, the temperature at the specific position (e.g., at a specific raw material position inside the cavity, at a specific position within the melt, or at a solid-liquid interface between the melt and the raw material) within the raw material or inside the cavity, or the average temperature across a plurality of positions, the temperature variance across a plurality of positions, the melt temperature distribution (e.g., a temperature distribution curve or a temperature distribution map), the raw material temperature distribution, the temperature distribution inside the cavity, etc., or any combination thereof.

In some embodiments, the control assembly may adjust the heating parameter of the laser heating assembly in real-time based on the temperature information related to the raw material or the cavity to grow high-quality crystals.

In some embodiments, the control assembly may perform simulation modeling based on the temperature information related to the raw material or the cavity, and further adjust the heating parameter of the laser heating assembly in real-time based on a simulation result. In some embodiments, the control assembly may construct a temperature model using techniques such as finite element analysis, MATLAB, regression techniques, artificial neural networks, or support vector machines, and adjust the heating parameter of the laser heating assembly in real-time based on the temperature model. In some embodiments, the temperature model may embody a global or overall temperature distribution inside the cavity. In some embodiments, the temperature model may reflect a temperature gradient inside the cavity (e.g., the axial temperature gradient, the radial temperature gradient).

In some embodiments, if the temperature model indicates that the temperature at a position is lower or higher than a preset temperature, the control assembly may increase or decrease the operating power of the at least two laser-emitting units to bring the temperature at the position in line or substantially in line with the preset temperature, or keep a difference between the two temperatures within a preset range (e.g., the difference is 0.01% of the preset temperature). For example, if the temperature model indicates that the temperature at the solid-liquid interface between a growing crystal and the raw material melt is lower or higher than a preset ideal growth temperature (the preset ideal growth temperature may be a system default or may be set by the user), the control assembly may increase or decrease the operating power of the at least two laser-emitting units.

In some embodiments, if the temperature model indicates that the temperature at a position is lower or higher than the preset temperature, the control assembly may adjust the at least two laser shaping and collimating lenses to adjust the size and/or shape of the laser beams emitted by the at least two laser-emitting units so that the temperature at the position is in line or substantially in line with the preset temperature or a difference between the two temperatures is within a preset range (e.g., the difference is 0.01% of the preset temperature). For example, if the temperature model indicates that the temperature at the solid-liquid interface between the growing crystal and the raw material melt is lower or higher than the preset temperature, the control assembly may adjust the at least two laser shaping and collimating lenses to increase or decrease the size of the laser beams emitted by the at least two laser-emitting units or to adjust the shape of the laser beams.

In some embodiments, if the temperature model indicates that the temperature gradient (e.g., the radial temperature gradient) is too large or too small, the control assembly may adjust the temperature gradient in real-time by adjusting the heating parameter of the at least two laser-emitting units. Further description can be found in FIG. 6 and the related descriptions thereof, which will not be repeated here.

In some embodiments, the control assembly may train a machine learning model based on historical crystal growth information (e.g., historical temperature information related to the raw material or the cavity, a historical heating parameter of the laser heating assembly, and a historical crystal-related parameter). Inputs of the machine learning model may include a crystal-related parameter (e.g., crystal type, crystal size, crystal properties, stage at which a crystal is growing, etc.), and outputs of the machine learning model may include the temperature information related to the raw material or the cavity and/or the heating parameter of the laser heating assembly. In some embodiments, the control assembly may monitor the crystal-related parameter in real-time and determine desired temperature information related to the raw material or the cavity and/or a desired heating parameter of the laser heating assembly based on a trained machine learning model. Further, the control assembly may automatically adjust the heating parameter of the laser heating assembly based on the desired temperature information related to the raw material or the cavity and/or the desired heating parameter of the laser heating assembly, thereby realizing an intelligent real-time temperature field adjustment during the crystal growth process.

Further description of adjusting the heating parameter of the laser heating assembly in real-time by the control assembly based on the temperature information can be found elsewhere in the present disclosure (e.g., FIG. 6 and the related descriptions thereof) and will not be repeated here.

In some embodiments, the crystal preparation device 100 may further include a feeding assembly (not shown in the figure) configured to feed material in real-time (e.g., real-time automatic material feeding) during the crystal growth process. The real-time material feeding can maintain a nearly constant melt concentration in the cavity during the crystal growth process, thereby enabling a grown crystal to exhibit high uniformity from top to bottom.

In some embodiments, the feeding assembly may include a weighing component, a mixing component, and a transferring component.

The weighing component may be configured to collect weight information of a growing crystal and/or weight information of supplementary material, and send the weight information to the control assembly. In some embodiments, the weighing component may include at least one weighing sensor. In some embodiments, the weighing sensor may include, but is not limited to, a photoelectric sensor, a hydraulic sensor, an electromagnetic force sensor, a capacitive sensor, a magneto-strictive sensor, a vibration sensor, a gyroscopic sensor, a resistive strain gauge sensor, etc., or any combination thereof. In some embodiments, the control assembly may obtain the weight information of the growing crystal and determine information related to supplementary material based on at least the weight information and a ratio of the raw material used to grow a crystal (e.g., a ratio between the respective reaction materials). In some embodiments, the information related to the supplementary material may include, but is not limited to, the composition of the supplementary material and the weight of each component. In some embodiments, the control assembly may control the weighing component to weigh each supplementary material, respectively.

The mixing component may be configured to mix the supplementary material homogeneously. In some embodiments, the control assembly may control the mixing component to mix the components of each supplementary material homogeneously.

The transferring component may be configured to transfer the supplementary material from the mixing component into the cavity. In some embodiments, the transferring component may include a conveying element and a power element, and the power element and the conveying element may be operatively connected. In some embodiments, the conveying element may include, but is not limited to, a geared conveyor belt. In some embodiments, the power element may include, but is not limited to, a motor.

In some embodiments, the crystal preparation device 100 may further include a liquid level sensor (not shown in the figure) configured to measure liquid surface position information (e.g., liquid surface height information) of a melt in the cavity and send the liquid surface position information to the control assembly.

In some embodiments, during the crystal growth process, the control assembly may control the cavity to move by controlling the shifting assembly 150 to move based on the liquid surface position information, thereby further maintaining a constant or substantially constant distance between the at least two laser-emitting units and a liquid surface of the melt, which can avoid a change in size of the beams emitted by the at least two laser-emitting units at the liquid surface of the melt due to a drop in the liquid surface of the melt during the crystal growth process, which further leads to a change in the temperature field and affects the normal growth of the crystal.

In some embodiments, the crystal preparation device 100 may further include a display assembly (not shown in the figure). In some embodiments, the display assembly may be configured to display crystal growth information in real-time, such as the temperature information related to the raw material or the cavity, the weight information of the growing crystal, the information related to the supplementary material, the heating parameter of the laser heating assembly, a lifting speed and/or rotation speed of the lifting assembly 120, crystal appearance, or the like. In some embodiments, the display assembly may include a liquid crystal display, a plasma display, a light-emitting diode display, etc., or any combination thereof.

In some embodiments, the crystal preparation device 100 may further include a storage assembly (not shown in the figure). The storage assembly may be configured to store data, instructions, and/or any other information. In some embodiments, the storage assembly may be configured to store data and/or information during the crystal preparation process. For example, the storage assembly may store the temperature information related to the raw material or the cavity during the crystal preparation process, the information related to supplementary material, the heating parameter of the laser heating assembly, data and/or instructions to accomplish the crystal preparation method described herein. In some embodiments, the storage assembly may include a USB flash drive, a removable hard drive, a CD-ROM, a memory card, etc., or any combination thereof.

It should be noted that the foregoing description of the crystal preparation device 100 is for the purpose of exemplification and illustration only, and does not limit the scope of application of the present disclosure. For a person skilled in the art, various corrections and changes can be made to the crystal preparation device 100 under the guidance of the present disclosure. However, these corrections and changes remain within the scope of the present disclosure. For example, the crystal preparation device 100 may be open, and the furnace 110 may be open so that an operator (e.g., a worker) can directly observe the insulation cylinder inside the furnace 110. The insulation cylinder is hermetically sealed and has no gas exchange with the atmosphere. As another example, the crystal preparation device 100 may be vacuum-based, with the interior of the furnace 110 being in a vacuum state, and the crystal preparation device 100 having no gas exchange with the atmosphere.

FIG. 2 is a schematic diagram illustrating an exemplary structure of a cavity according to some embodiments of the present disclosure.

In some embodiments, as shown in FIG. 2, a cavity 200 may include a cooling structure 210 configured to lower the temperature of the cavity 200 to avoid contamination of raw material (e.g., a raw material melt) by the cavity 200 due to volatilization from the high temperature, which further can ensure the quality of a grown crystal. In some embodiments, a cooling medium (e.g., cooling gas, cooling water, cooling oil) may be introduced into the cooling structure 210 to cool the cavity 200.

In some embodiments, the cavity 200 may be a single cavity having a hollow structure, and the hollow structure may form the cooling structure 210.

In some embodiments, as shown in FIG. 2, the cavity 200 may include an inner cavity body 220 and an outer cavity body 230, and the inner cavity body 220 and the outer cavity body 230 may be enclosed to form the cooling structure 210. In some embodiments, the inner cavity body 220 and the outer cavity body 230 may be integrally molded or fixedly connected (e.g., welded, glued, etc.). In some embodiments, the inner cavity body 220 and the outer cavity body 230 may be detachably connected (e.g., snap-fit, etc.) to facilitate replacement (e.g., of the inner cavity body 220 or the outer cavity body 230), thereby reducing the cost of the cavity 200 and further reducing the cost of preparing a crystal. In some embodiments, the inner cavity body 220 and the outer cavity body 230 are detachably connected to the crystal preparation device 100.

In some embodiments, the cooling structure 210 may include at least one inlet 211, at least one outlet 212, and a cooling channel 213, as shown in FIG. 2. In some embodiments, the cooling medium may flow into the cooling channel 213 through the at least one inlet 211 and flow out through the at least one outlet 212 to reduce the temperature of a portion of the cavity 200 close to the raw material. In some embodiments, the height of the at least one inlet 211 may be lower than the height of the at least one outlet 212 to increase the utilization of the cooling medium.

In some embodiments, the material of the cavity 200 may include a metallic material such as copper, iron, stainless steel, or the like, to reduce the cost of the cavity 200, and further reduce the cost of preparing the crystal while guaranteeing the quality of the crystal. In some embodiments, the material of the cavity 200 may also include graphite, quartz, alumina, zirconia, or the like. In some embodiments, the material of the inner cavity body 220 and the outer cavity body 230 may be the same or different. For example, the material of both the inner cavity body 220 and the outer cavity body 230 may be copper. As another example, the material of the inner cavity body 220 is copper and the material of the outer cavity body 230 is graphite. The embodiments of the present disclosure do not limit the purity of the material of the cavity 200 in any way.

FIG. 3 is a schematic diagram illustrating an exemplary structure of a cavity and an insulation assembly according to some embodiments of the present disclosure.

In some embodiments, an insulation assembly 300 may at least partially encircle the cavity 200. For example, the insulation assembly 300 may be disposed around an outer periphery of the cavity 200, as shown in FIG. 3.

In some embodiments, as shown in FIG. 3, the insulation assembly 300 may include an upper insulation component 310, a middle insulation component 320, and a lower insulation component 330.

In some embodiments, the upper insulation component 310 may include a first gap 311 for allowing at least a portion of the lifting assembly 120 to extend into the cavity 200 to move up and down and/or rotate for crystal growth. In some embodiments, the upper insulation component 310 may also include at least two through-holes 312 for laser beams emitted by at least two laser-emitting units to be directed into the cavity 200. In some embodiments, the at least two through-holes 312 may correspond to the at least two laser-emitting units and be arranged in the same manner.

In some embodiments, the middle insulation component 320 may be arranged to surround above the cavity 200. The middle insulation component 320 may be tightly connected to the upper insulation component 310 and the lower insulation component 330.

In some embodiments, the lower insulation component 330 may be disposed around an outer side wall of the cavity 200 to insulate the cavity 200. In some embodiments, the at least one inlet 211 and the at least one outlet 212 may not be provided with an insulation component to facilitate the flow of cooling medium into and out of the cooling channel 213.

In some embodiments, the form of the insulation assembly 300 may include block insulation material, flocculent insulation material, lamellar insulation material, or the like. In some embodiments, the material of the insulation assembly 300 may include a high-temperature-resistant material such as metal, alumina, zirconia, silica, tempered aluminum, carbide, nitride, silicide, or the like. In some embodiments, the upper insulation component 310, the middle insulation component 320, and the lower insulation component 330 may be of the same form and/or material or different.

In some embodiments, the crystal preparation device may further include a tray assembly 400 configured to support the cavity 200 and the insulation assembly 300. In some embodiments, the tray assembly 400 may include a tray through-hole 410, and the tray through-hole 410 is in communication with the at least one inlet 211 to facilitate the flow of cooling medium into the cooling channel 213.

FIG. 4A is a schematic diagram illustrating a top view of a furnace cover according to some embodiments of the present disclosure. FIG. 4B is a schematic diagram illustrating a top view of a furnace cover according to some other embodiments of the present disclosure.

In some embodiments, as shown in FIG. 4A and FIG. 4B, the furnace cover 112 may be provided with a first through-hole 1121 through which at least a portion of the lifting assembly 120 may extend into the furnace 110 or cavity to move up and down and/or rotate to grow a crystal. In some embodiments, the concentricity between the first through-hole 1121 and the cavity may be less than 10 mm. In some embodiments, the concentricity between the first through-hole 1121 and the cavity may be less than 8 mm. In some embodiments, the concentricity between the first through-hole 1121 and the cavity may be less than 6 mm. In some embodiments, the concentricity between the first through-hole 1121 and the cavity may be less than 4 mm. In some embodiments, the concentricity between the first through-hole 1121 and the cavity may be less than 2 mm.

In some embodiments, at least two laser-emitting units 500 may be installed on the furnace cover 112, as shown in FIG. 4A and FIG. 4B. In some embodiments, the at least two laser-emitting units 500 may be distributed along a circumferential direction of the furnace cover 112. In some embodiments, the at least two laser-emitting units 500 may be distributed along the circumferential direction of the furnace cover 112 to form at least one ring-like shape, facilitating precise adjustment of a temperature gradient (e.g., a radial temperature gradient) required for crystal growth during a crystal growth process. For example, as shown in FIG. 4A, the at least two laser-emitting units 500 may be distributed along the circumferential direction of the furnace cover 112 to form a ring-like shape on the furnace cover 112 centered on the first through-hole 1121 (as shown by dashed line a in FIG. 4A). As another example, as shown in FIG. 4B, the at least two laser-emitting units 500 may be distributed along the circumferential direction of the furnace cover 112 to form two ring-like shapes on the furnace cover 112 centered on the first through-hole 1121 (as shown by dashed lines b1 and b2, respectively, in FIG. 4B).

In some embodiments, the radius of an outermost ring-like shape formed by the at least two laser-emitting units 500 along the circumferential direction (e.g., shown by a dashed line a in FIG. 4A and the dashed line b1 in FIG. 4B) may be smaller than the radius of the cavity, so that laser beams emitted by the at least two laser-emitting units 500 can provide a temperature field required for crystal growth while avoiding excessive heating of side walls of the cavity, thereby further preventing cavity volatilization from affecting the quality of the crystal. Merely by way of example, in conjunction with FIG. 2, since the radius of the outermost ring-like shape formed by the at least two laser-emitting units 500 along the circumferential direction is smaller than the radius of the cavity, raw material close to a central portion of the cavity 200 and around the ring-like shape is melted to form a melt A, while raw material B located close to side walls of the cavity 200 remains unmelted. With this ring-like heating manner, the cavity 200 can be prevented from contaminating the raw material due to volatilization caused by high temperature.

A difference between the radius of the outermost ring-like shape formed by the at least two laser-emitting units 500 along the circumferential direction (as shown by R in FIG. 4B) and the radius of the cavity can affect the utilization of the raw material and the quality of the crystal. For example, the difference between the radius of the outermost ring-like shape and the radius of the cavity being too large can result in a large portion of the raw material inside the cavity not being able to be melted to form a melt, which further results in a lower utilization of the raw material. As another example, the difference between the radius of the outermost ring-like shape and the radius of the cavity being too small can result in the temperature of the side walls of the cavity being excessively high, leading to volatilization and further contaminating the raw material inside the cavity (e.g., the raw material melt), which affects the quality of the crystal. Thus, in some embodiments, the difference between the radius of the outermost ring-like shape and the radius of the cavity is required to satisfy a preset requirement to increase the utilization rate of the raw material and ensure the quality of the crystal.

In some embodiments, the difference between the radius of the outermost ring-like shape and the radius of the cavity may be in a range of 50 mm to 500 mm. In some embodiments, the difference between the radius of the outermost ring-like shape and the radius of the cavity may be in a range of 100 mm to 500 mm. In some embodiments, the difference between the radius of the outermost ring-like shape and the radius of the cavity may be in a range of 120 mm to 480 mm. In some embodiments, the difference between the radius of the outermost ring-like shape and the radius of the cavity may be in a range of 150 mm to 450 mm. In some embodiments, the difference between the radius of the outermost ring-like shape and the radius of the cavity may be in a range of 180 mm to 420 mm. In some embodiments, the difference between the radius of the outermost ring-like shape and the radius of the cavity may be in a range of 200 mm to 400 mm. In some embodiments, the difference between the radius of the outermost ring-like shape and the radius of the cavity may be in a range of 220 mm to 380 mm. In some embodiments, the difference between the radius of the outermost ring-like shape and the radius of the cavity may be in a range of 250 mm to 350 mm. In some embodiments, the difference between the radius of the outermost ring-like shape and the radius of the cavity may be in a range of 280 mm to 320 mm. In some embodiments, the difference between the radius of the outermost ring-like shape and the radius of the cavity may be in a range of 50 mm to 200 mm. In some embodiments, the difference between the radius of the outermost ring-like shape and the radius of the cavity may be in a range of 50 mm to 100 mm. In some embodiments, the difference between the radius of the outermost ring-like shape and the radius of the cavity may be in a range of 100 mm to 200 mm. In some embodiments, the difference between the radius of the outermost ring-like shape and the radius of the cavity may be in a range of 400 mm to 500 mm. In some embodiments, the difference between the radius of the outermost ring-like shape and the radius of the cavity may be in a range of 400 mm to 450 mm. In some embodiments, the difference between the radius of the outermost ring-like shape and the radius of the cavity may be in a range of 450 mm to 500 mm.

In some embodiments, the difference between the radius of the outermost ring-like shape and the radius of the cavity may be 0.5 times to 5 times the diameter of a crystal to be grown. In some embodiments, the difference between the radius of the outermost ring-like shape and the radius of the cavity may be 1 time to 4.5 times the diameter of the crystal to be grown. In some embodiments, the difference between the radius of the outermost ring-like shape and the radius of the cavity may be 1.5 times to 4 times the diameter of the crystal to be grown. In some embodiments, the difference between the radius of the outermost ring-like shape and the radius of the cavity may be 2 times to 3.5 times the diameter of the crystal to be grown. In some embodiments, the difference between the radius of the outermost ring-like shape and the radius of the cavity may be 2.5 times to 3 times the diameter of the crystal to be grown.

The radius of the outermost ring-like shape formed by the at least two laser-emitting units 500 along the circumferential direction (shown by R in FIG. 4B) affects the quality of the crystal. For example, the radius of the outermost ring-like shape being too small results in higher thermal stresses within a growing crystal, further resulting in a crystal prone to cracking. As another example, the radius of the outermost ring-like shape being too large results in a larger volume of melt formed by the raw material inside the cavity, and its flow rate can affect the crystal growth interface, which further results in more surface striations on the growing crystal, impacting the optical uniformity of the crystal. Thus, in some embodiments, the radius of the outermost ring-like shape is required to satisfy a preset requirement to improve the quality of the crystal.

In some embodiments, the radius of the outermost ring-like shape may be 1.21 times to 3.5 times the diameter of the crystal to be grown. In some embodiments, the radius of the outermost ring-like shape may be 1.5 times to 3.2 times the diameter of the crystal to be grown. In some embodiments, the radius of the outermost ring-like shape may be 1.8 times to 3 times the diameter of the crystal to be grown. In some embodiments, the radius of the outermost ring-like shape may be 2 times to 2.8 times the diameter of the crystal to be grown. In some embodiments, the radius of the outermost ring-like shape may be 2.2 times to 2.6 times the diameter of the crystal to be grown. In some embodiments, the radius of the outermost ring-like shape may be 2.3 times to 2.5 times the diameter of the crystal to be grown.

A radius of an innermost ring-like shape formed by the at least two laser-emitting units 500 along the circumferential direction (as shown by r in FIG. 4B) affects the crystal growth. For example, the radius of the innermost ring-like shape being too large results in the raw material close to the center portion of the cavity not being melted to form a melt or being melted insufficiently, which further results in the inability to grow the crystal. As another example, the radius of the innermost ring-like shape being too small results in the raw material close to the center portion of the cavity being too hot, further resulting in the melt not being able to crystallize to grow the crystal. Thus, in some embodiments, the radius of the innermost ring-like shape is required to satisfy a preset requirement for the crystal to grow properly.

In some embodiments, the radius of the innermost ring-like shape may be in a range of 25 mm to 300 mm. In some embodiments, the radius of the innermost ring-like shape may be in a range of 30 mm to 270 mm. In some embodiments, the radius of the innermost ring-like shape may be in a range of 50 mm to 250 mm. In some embodiments, the radius of the innermost ring-like shape may be in a range of 70 mm to 230 mm. In some embodiments, the radius of the innermost ring-like shape may be in a range of 100 mm to 200 mm. In some embodiments, the radius of the innermost ring-like shape may be in a range of 120 mm to 180 mm. In some embodiments, the radius of the innermost ring-like shape may be in a range of 150 mm to 160 mm. In some embodiments, the radius of the innermost ring-like shape may be in a range of 20 mm to 100 mm. In some embodiments, the radius of the innermost ring-like shape may be in a range of 20 mm to 50 mm. In some embodiments, the radius of the innermost ring-like shape may be in a range of 50 mm to 100 mm. In some embodiments, the radius of the innermost ring-like shape may be in a range of 200 mm to 300 mm. In some embodiments, the radius of the innermost ring-like shape may be in a range of 200 mm to 250 mm. In some embodiments, the radius of the innermost ring-like shape may be in a range of 25 mm to 300 mm.

In some embodiments, the radius of the innermost ring-like shape may be 1.2 times to 3 times the diameter of the crystal to be grown. In some embodiments, the radius of the innermost ring-like shape may be 1.4 times to 2.8 times the diameter of the crystal to be grown. In some embodiments, the radius of the innermost ring-like shape may be 1.6 times to 2.6 times the diameter of the crystal to be grown. In some embodiments, the radius of the innermost ring-like shape may be 1.8 times to 2.4 times the diameter of the crystal to be grown. In some embodiments, the radius of the innermost ring-like shape may be 2 times to 2.2 times the diameter of the crystal to be grown.

A radius difference between adjacent ring-like shapes (e.g., a difference between R and r in FIG. 4B) among the at least two ring-like shapes formed by the at least two laser-emitting units 500 along the circumferential direction affects the control of the temperature field (or temperature gradient) and/or the installation of the at least two laser-emitting units 500. For example, the radius difference between adjacent ring-like shapes being too large results in difficulty in accurately regulating the radial temperature gradient, further affecting the quality of the crystal. As another example, the radius difference between adjacent ring-like shapes being too small results in difficulty in installing the at least two laser-emitting units 500. In addition, the radius difference between adjacent ring-like shapes being too small may result in difficulty in precisely controlling the overlap of the laser beams emitted by the laser-emitting units on adjacent ring-like shapes, which in turn can make it challenging to accurately control the radial temperature gradient. Therefore, in some embodiments, the radius difference between adjacent ring-like shapes is required to satisfy a preset requirement to ensure the quality of the crystal and to facilitate the installation of the at least two laser-emitting units 500.

In some embodiments, the radius difference between adjacent ring-like shapes may be in a range of 5 mm to 200 mm. In some embodiments, the radius difference between adjacent ring-like shapes may be in a range of 20 mm to 180 mm. In some embodiments, the radius difference between adjacent ring-like shapes may be in a range of 40 mm to 160 mm. In some embodiments, the radius difference between adjacent ring-like shapes may be in a range of 60 mm to 140 mm. In some embodiments, the radius difference between adjacent ring-like shapes may be in a range of 80 mm to 120 mm. In some embodiments, the radius difference between adjacent ring-like shapes may be in a range of 50 mm to 200 mm. In some embodiments, the radius difference between adjacent ring-like shapes may be in a range of 50 mm to 100 mm.

FIG. 5 is a schematic diagram illustrating an exemplary installation structure of at least two laser-emitting units according to some embodiments of the present disclosure. In conjunction with FIG. 4A, FIG. 5 is a schematic diagram illustrating a cross-sectional view of a portion in FIG. 4A along A-A. The at least two laser-emitting units are not shown in FIG. 5.

In some embodiments, at least two laser input windows 1122 may be disposed on the furnace cover 112 for installing the at least two laser shaping and collimating lenses, as shown in FIG. 5. The at least two laser input windows 1122 may correspond to laser output ports of the at least two laser-emitting units, so that the laser beams emitted by the at least two laser-emitting units can be input into the cavity 200.

In some embodiments, the laser input window 1122 may include a laser input window top cover 11221, a laser input window column 11222, and a connecting member 11223, as shown in FIG. 5.

In some embodiments, the laser input window top cover 11221 may be provided with a second through-hole for installing a window (e.g., glass). In some embodiments, the laser input window top cover 11221 may be an integrated window structure without the second through-hole. In some embodiments, the laser input window top cover 11221 and the laser input window column 11222 may be detachably connected (e.g., bolted). In some embodiments, the laser input window top cover 11221 and the laser input window column 11222 may be hermetically connected by a sealing ring. In some embodiments, the connecting member 11223 may be disposed within the laser input window column 11222 and located below the laser input window top cover 11221. In some embodiments, the material of the connecting member 11223 may include, but is not limited to, quartz for transmitting laser beams to be incident within the cavity 200 to heat raw material.

In some embodiments, the furnace cover 112 may also include a cooling pathway 1123 for introducing a cooling medium (e.g., cooling gas, cooling water, cooling oil) to reduce the temperature of the furnace cover 112. In some embodiments, the furnace cover 112 may further include a pathway inlet 1124 and a pathway outlet 1125, and the cooling medium may flow into the cooling pathway 1123 through the pathway inlet 1124 and flow out through the pathway outlet 1125. In some embodiments, the height of the pathway inlet 1124 may be lower than the height of the pathway outlet 1125, which can improve the utilization of the cooling medium.

In some embodiments, the first through-hole 1121, the at least two laser input windows 1122, and the cooling pathway 1123 may be independent of each other, or not connected.

In some embodiments, as shown in FIG. 5, the furnace cover 112 may also be provided with a pathway 1126 for allowing the lifting assembly 120 to pass through for moving up and down and/or rotating. The pathway 1126 is connected to the first through-hole 1121.

FIG. 6 is a flowchart illustrating a process of a crystal preparation method according to some embodiments of the present disclosure. A process 600 may be performed by one or more assemblies of a crystal preparation device (e.g., the crystal preparation device 100). In some embodiments, the process 600 may be automatically executed by a control system. For example, the process 600 may be realized by a control instruction, and the control system, based on the control instruction, controls the assemblies to complete the various operations of the process 600. In some embodiments, the process 600 may be executed semi-automatically. For example, one or more operations of the process 600 may be manually performed by an operator. In some embodiments, one or more additional operations not described herein may be added, and/or one or more operations discussed herein may be deleted when completing the process 600. As shown in FIG. 6, the process 600 may include the following steps. In step 610, raw material is placed in a cavity (e.g., the cavity 200).

In some embodiments, the raw material refers to reaction material required to grow a crystal. In some embodiments, the raw material may be reaction material that has been pretreated. In some embodiments, the pretreatment may include, but is not limited to, roasting, blending, pressing, etc., or any combination thereof. In some embodiments, the weight of the raw material may be determined based on a chemical reaction equation of a crystal to be grown.

In step 620, the raw material is heated by a laser heating assembly to melt a portion of the raw material into a raw material melt.

In some embodiments, in conjunction with FIG. 4A, FIG. 4B, and the related descriptions thereof, the laser heating assembly may include at least two laser-emitting units, and the at least two laser-emitting units may be distributed along a circumferential direction of a furnace cover to form at least one ring-like shape. Through the at least one ring-like shape, the laser heating assembly may form a ring-like heating zone inside the cavity (e.g., shown by “X” in FIG. 7). In some embodiments, the at least two laser-emitting units emit laser beams to the ring-like heating zone to heat the raw material located within the ring-like heating zone. Accordingly, the raw material located within and close to the ring-like heating zone (in this present disclosure, “close to” refers to within a preset range (e.g., 1 cm, 2 cm, 5 cm)) is melted into a raw material melt, while the raw material located away from the ring-like heating zone is not melted. That is, as shown in FIG. 2 and FIG. 7, the raw material between the ring-like heating zone and the center portion of the cavity 200 melts into the raw material melt A, while the raw material B away from the center portion of the cavity 200 and the ring-like heating zone (i.e., close to the side wall of the cavity 200) is not melted.

In step 630, a crystal growth process is performed based on the raw material melt, wherein a heating parameter of the laser heating assembly is adjusted in real-time during the crystal growth process.

In some embodiments, the crystal growth method may include a Czochralski method, a Bridgman method, or the like. The following will illustrate a crystal growth process using the Czochralski method. A crystal growth process using the Czochralski method may include processes such as seed crystal preheating, seeding, temperature adjustment, necking, shoulder growth, constant diameter growth, tailing growth, cooling, and crystal extraction.

The seed crystal preheating refers to, during a melting process (e.g., in step 620), fixing a seed crystal to the top of a lifting rod and gradually lowering it into the temperature field, so that the temperature of the seed crystal approaches the temperature of a raw material melt, which prevents the seed crystal, being at a lower temperature, from cracking upon contact with the raw material melt in subsequent operations. In some embodiments, the seed crystal may be prepared based on physical vapor transport (PVT), chemical vapor deposition (CVD), a Czochralski method, or the like.

The seeding refers to, after a portion of the raw material has been melted into the raw material melt, lowering a lifting assembly (e.g., the lifting assembly 120) to bring the seed crystal into contact with the raw material melt.

The temperature adjustment refers to adjusting the current temperature inside a crystal preparation device (e.g., the crystal preparation device 100) to a growth temperature suitable for a crystal to be grown.

The necking refers to gradually increasing the temperature such that the temperature at the center point of the liquid surface of the raw material melt (e.g., the raw material melt A in FIG. 2) is slightly higher than the melting point of the crystal to be grown, thereby causing the diameter of a newly grown crystal to gradually decrease during the process in which the seed crystal (e.g., a seed crystal C in FIG. 2) is rotated and lifted.

The shoulder growth refers to the process in which when the atoms or molecules at the solid-liquid interface between the seed crystal and the raw material melt begin to arrange themselves in accordance with the structure of the seed crystal, the temperature of the temperature field is slowly lowered according to the real-time growth rate of the crystal, so as to make the seed crystal expand in accordance with a preset angle.

The constant diameter growth refers to the growth of the crystal into an equal-diameter rod-like structure according to a preset diameter attained in the process of shoulder growth.

The tailing growth refers to the process in which, after the crystal has grown to a predetermined length, the crystal is raised until it is completely separated from the melt. The tailing growth can be the inverse operation of the shoulder growth.

The cooling refers to a gradual cooling method employed after the tailing growth is completed, aimed at relieving the stress formed in the crystal during high-temperature growth and preventing cracking caused by a sudden temperature drop.

The crystal extraction refers to opening the crystal preparation device (e.g., the crystal preparation device 100) and removing the grown crystal (e.g., a crystal D in FIGS. 2 and 7) when the internal temperature inside the crystal preparation device (e.g., the crystal preparation device 100) is reduced to room temperature.

In some embodiments, one or more steps during the crystal growth process may be controlled by the control assembly or a PID (proportional, integral, differential) controller, including, but are not limited to, the processes of necking, shoulder growth, constant diameter growth, tailing growth, cooling, or the like. In some embodiments, the solid-liquid interface between the seed crystal and the raw material melt may also be controlled to be horizontal.

In some embodiments, the temperature gradient may be adjusted in real-time during the crystal growth process by adjusting the heating parameter of the laser heating assembly (e.g., the operating power of the laser heating assembly, the shape and/or size of the laser beam of the laser heating assembly).

In some embodiments, the temperature gradient during the crystal growth process includes an axial temperature gradient and/or a radial temperature gradient. The radial temperature gradient is described below as an example.

In some embodiments, the radial temperature gradient during the crystal growth process may include a first temperature gradient and a second temperature gradient. The first temperature gradient refers to a temperature gradient along a direction (e.g., the direction shown by the dashed arrow x in FIG. 7) from the ring-like heating zone to a crystal growth center point (e.g., a center point O in FIG. 7), and the second temperature gradient refers to a temperature gradient along a direction (e.g., the direction shown by the dashed arrow y in FIG. 7) from the ring-like heating zone to the inner wall of the cavity. In some embodiments, the first temperature gradient and the second temperature gradient are both negative temperature gradients by controlling the heating parameter of the laser heating assembly. That is, along the direction from the ring-like heating zone to the crystal growth center point, the temperature is gradually reduced, which can accordingly provide the power of crystal growth; and along the direction from the ring-like heating zone to the inner wall of the cavity, the temperature is gradually reduced, which can avoid the contamination of the raw material due to volatilization of the side wall of the cavity.

In some embodiments, in conjunction with the foregoing mentioned, the at least two laser-emitting units may be distributed along the circumferential direction of the furnace cover to form a plurality of ring-like shapes, and accordingly, the ring-like heating zone may include a plurality of sub-ring-like zones corresponding to the plurality of ring-like shapes, respectively. In some embodiments, the temperature of the plurality of sub-ring-like zones decreases gradually from outside to inside (i.e., along the direction from the ring-like heating zone to the crystal growth center point), thereby creating a negative temperature gradient along the x-direction (i.e., the first temperature gradient). Merely by way of example, in conjunction with FIG. 4B, the at least two laser-emitting units are distributed along the circumferential direction of the furnace cover to form two ring-like shapes b1 and b2, and correspondingly, as shown in FIG. 7, the two ring-like shapes b1 and b2 form two ring-like heating zones Y and Z, respectively, and the temperature of the ring-like heating zone Y is higher than the temperature of the ring-like heating zone Z.

In some embodiments, the first temperature gradient and/or the second temperature gradient may be adjusted in real-time during the crystal growth process by adjusting the heating parameters of the at least two laser-emitting units. In some embodiments, the heating parameter of the laser-emitting unit may include an operating power of the laser-emitting unit, the shape of a laser beam, the size of the laser beam, or the like, or any combination thereof. In some embodiments, a temperature and/or a range of the ring-like heating zone may be adjusted by adjusting the heating parameters of the at least two laser-emitting units, thereby adjusting the first temperature gradient and/or the second temperature gradient. In some embodiments, the temperatures and/or ranges of a plurality of sub-ring-like zones may be adjusted by adjusting heating parameters of laser-emitting units corresponding to the plurality of sub-ring-like zones, respectively, thereby adjusting the first temperature gradient and/or the second temperature gradient.

In some embodiments, the temperature of the ring-like heating zone (or a plurality of sub-ring-like zones) can be increased or decreased by increasing or decreasing the operating power of the at least two laser-emitting units, and accordingly, the adjustment of the temperature gradient can be realized. Merely by way of example, during the crystal growth process, if the first temperature gradient (an absolute value of the temperature gradient is taken as an example for convenience of description) is lower than a preset temperature gradient (which can be a system default or can be set by the user), i.e., if the temperature gradient along the direction from the ring-like heating zone to the crystal growth center point is lower than the preset temperature gradient, the operating power of laser-emitting units corresponding to an outer sub-ring-like zone can be increased (to increase the temperature of the outer sub-ring-like zone) and/or the operating power of laser-emitting units corresponding to an inner sub-ring-like zone can be decreased (to decrease the temperature of the inner sub-ring-like zone), thereby increasing the first temperature gradient so that the first temperature gradient is in line with or substantially in line with the preset temperature gradient, or so that a temperature gradient difference between the first temperature gradient and the preset temperature gradient is within a preset range (e.g., 0.01% of the preset temperature gradient). As another example, during the crystal growth process, if the first temperature gradient is higher than the preset temperature gradient, i.e., the temperature gradient along the direction from the ring-like heating zone to the crystal growth center point is higher than the preset temperature gradient, the operating power of the laser-emitting units corresponding to the outer sub-ring-like zone may be reduced (to reduce the temperature of the outer sub-ring-like zone) and/or the operating power of the laser-emitting units corresponding to the inner sub-ring-like zone may be increased (to increase the temperature of the inner sub-ring-like zone), thereby decreasing the first temperature gradient so that the first temperature gradient is in line with or substantially in line with the preset temperature gradient, or so that the temperature gradient difference between the first temperature gradient and the preset temperature gradient is within a preset range (e.g., 0.01% of the preset temperature gradient).

In some embodiments, the size of laser beams emitted by the at least two laser shaping and collimating lenses can be changed by adjusting the at least two laser-emitting units to adjust the temperature of the ring-like heating zone (or the plurality of sub-ring-like zones), and accordingly, the adjustment of the temperature gradient can be realized.] Merely by way of example only, during the crystal growth process, if the first temperature gradient (for convenience of description, the absolute value of the temperature gradient is taken as an example) is lower than the preset temperature gradient (which can be a system default or can be set by the user), i.e., if the temperature gradient along the direction from the ring-like heating zone to the crystal growth center point is lower than the preset temperature gradient, laser shaping and collimating lenses corresponding to the outer sub-ring-like zone can be adjusted to make the size of the corresponding laser beam smaller (so that the energy of the laser beam is more concentrated to increase the temperature of the outer sub-ring-like zone) and/or laser shaping and collimating lenses corresponding to the inner sub-ring-like zone cam be adjusted to make the size of the corresponding laser beam larger (so that the energy of the laser beam is dispersed (assuming that adjacent laser beams do not overlap) to decrease the temperature of the inner sub-ring-like zone), thereby increasing the first temperature gradient so that the first temperature gradient is in line with or substantially in line with the preset temperature gradient, or so that the temperature gradient difference between the first temperature gradient and the preset temperature gradient is within a preset range (e.g., 0.01% of the preset temperature gradient). As another example, if the first temperature gradient is higher than the preset temperature gradient, i.e., the temperature gradient along the direction from the ring-like heating zone to the crystal growth center point is higher than the preset temperature gradient, the laser shaping and collimating lenses corresponding to the outer sub-ring-like zone may be adjusted to make the size of the corresponding laser beam larger (to make the energy of the laser beam diffused (assuming that adjacent laser beams do not overlap) to decrease the temperature of the outer sub-ring-like zone) and/or the laser shaping and collimating lenses corresponding to the inner sub-ring-like zone may be adjusted to make the size of the corresponding laser beam smaller (so that the energy of the laser beam is more focused to increase the temperature of the inner sub-ring-like zone), thereby decreasing the first temperature gradient so that the first temperature gradient is in line with or substantially in line with the preset temperature gradient, or so that the temperature gradient difference between the first temperature gradient and the preset temperature gradient is within a preset range (e.g., 0.01% of the preset temperature gradient).

In some embodiments, the degree of overlap of the laser beams emitted by the at least two laser-emitting units may be adjusted by adjusting the size and/or shape of the laser beams through the at least two laser shaping and collimating lenses, which enables the temperature of the ring-like heating zone (or the plurality of sub-ring-like zones) to be controlled accordingly, thereby realizing the adjustment of the temperature gradient. Merely by way of example, during the crystal growth process, if the first temperature gradient (the absolute value of the temperature gradient is taken as an example for convenience of description) is lower than the preset temperature gradient (which can be a system default or can be set by the user), i.e., if the temperature gradient along the direction from the ring-like heating zone to the crystal growth center point is lower than the preset temperature gradient, the laser shaping and collimating lenses corresponding to the outer sub-ring-like zone may be adjusted to adjust the size and/or shape of the corresponding laser beam such that adjacent laser beams at least partially overlap (to increase the temperature of the outer sub-ring-like zone), or the laser shaping and collimating lenses corresponding to the inner sub-ring-like zone may be adjusted to adjust the size and/or shape of the corresponding laser beam such that the overlapping region between adjacent laser beams is reduced (to decrease the temperature of the inner sub-ring-like zone), thereby increasing the first temperature gradient so that the first temperature gradient is in line with or substantially in line with the preset temperature gradient, or so that the temperature gradient difference between the first temperature gradient and the preset temperature gradient is within a preset range (e.g., 0.01% of the preset temperature gradient). As another example, during the crystal growth process, if the first temperature gradient is higher than the preset temperature gradient, i.e., the temperature gradient along the direction from the ring-like heating zone to the crystal growth center point is higher than the preset temperature gradient, the laser shaping and collimating lenses corresponding to the outer sub-ring-like zone may be adjusted to adjust the size and/or shape of the corresponding laser beam such that the overlapping region between adjacent laser beams is reduced (to decrease the temperature of the outer sub-ring-like zone), or the laser shaping and collimating lenses corresponding to the inner sub-ring-like zone may be adjusted to adjust the size and/or shape of the corresponding laser beam such that adjacent laser beams at least partially overlap (to increase the temperature of the inner sub-ring-like zone), thereby decreasing the first temperature gradient so that the first temperature gradient is in line with or substantially in line with the preset temperature gradient, or so that the temperature gradient difference between the first temperature gradient and the preset temperature gradient is within a preset range (e.g., 0.01% of the preset temperature gradient).

In some embodiments, taking one sub-ring-like zone as an example, heating parameters of a plurality of laser-emitting units corresponding to the sub-ring-like zone may also be adjusted, respectively, to achieve precise control of the temperature at various position points along a circumferential direction of the sub-ring-like zone. In some embodiments, the heating parameters (e.g., an operating power, a shape of a laser beam, a size of the laser beam) of a plurality of laser-emitting units corresponding to adjacent sub-ring-like zones, respectively, may also be adjusted in a linked manner to achieve linked precise control of the temperature and/or range of the adjacent sub-ring-like zones, thereby achieving continuous precise control of the radial temperature gradient.

In some embodiments, simulation modeling may be performed based on the temperature information related to the raw material or the cavity, and further, the heating parameter of the laser heating assembly may be adjusted in real-time based on a simulation result. In some embodiments, a temperature model may be constructed through finite element analysis, MATLAB, a regression technique, an artificial neural network, a support vector machine, or the like, and the heating parameter of the laser heating assembly may be adjusted in real-time based on the temperature model. In some embodiments, the temperature model may embody a global or overall temperature distribution inside the cavity. In some embodiments, the temperature model may reflect a temperature gradient inside the cavity (e.g., the axial temperature gradient, the radial temperature gradient).

More descriptions of the cavity, the laser heating assembly, the heating parameter of the laser heating assembly, the temperature information related to the raw material or the cavity, the simulation modeling based on the temperature information related to the raw material or the cavity, and the adjustment of the heating parameter of the laser heating assembly based on the simulation result can be found in other parts of the present disclosure (e.g., FIG. 1 and the description thereof), which will not be repeated herein.

In some embodiments, the melt concentration in the cavity may also be kept constant during the crystal growth process by real-time feeding (e.g., real-time automated feeding) to enable high homogeneity of grown crystals. In some embodiments, supplementary material may be added to a position inside the cavity corresponding to an outer ring-like zone (e.g., the ring-like zone indicated by Y in FIG. 7) to allow for rapid melting of the supplementary material to form a melt. A description of the real-time feeding can be found elsewhere in the present disclosure (e.g., FIG. 1 and its description) and will not be repeated here.

It should be noted that the foregoing description of the process 600 is intended to be exemplary and illustrative only and does not limit the scope of application of the present disclosure. For a person skilled in the art, various corrections and changes can be made to the process 600 under the guidance of the present disclosure. However, these corrections and changes remain within the scope of the present disclosure.

### Embodiment 1: Growth of a Lithium Tantalate (LT) Crystal (LiTaO₃)

Installing steps of a crystal preparation device were performed.

In step 1, a level of a tray assembly was adjusted, and the level is required to be less than 0.1 mm/m.

In step 2, a distance between a lower end surface of a cavity and a bottom plate was adjusted to be no less than 100 mm.

In step 3, a concentricity between the cavity and a lifting assembly was adjusted to be less than 3 mm.

In step 4, raw material required for growing the LT crystal was loaded into the cavity.

In step 5, an insulation cylinder and an upper sealing cover were installed.

In step 6, a furnace cover was installed.

In step 7, laser emitters were installed on the furnace cover. Laser shaping and collimating lenses were installed on an upper end surface of a laser input window and a laser aperture size and relative position were confirmed. A total of 6 laser emitters and 6 corresponding laser shaping and collimating lenses were installed. Among the 6 laser emitters, 3 laser emitters formed 1 ring-like shape, and a total of 2 ring-like shapes were formed. A radius difference between adjacent ring-like shapes was 50 mm. The radius of an innermost ring-like shape was 220 mm, and the radius of an outermost ring-like shape was 270 mm.

In step 8, a lifting assembly was installed.

Reaction materials required for growing the LT crystal include Tantalum Pentoxide (Ta₂O₅) and Lithium Carbonate (Li₂CO₃), each of which has a purity greater than or equal to 99.999%, and each of which is obtained by high-temperature roasting at 800° C. for 5 hours and then cooling to room temperature. The molar ratio of each reaction material was calculated according to the following reaction equation: Ta₂O₅+Li₂CO₃=2LiTaO₃+CO₂←, where Li₂CO₃ is used in excess by 0.001% to 10% of its theoretical weight (i.e., the theoretical weight calculated based on the reaction equation).

After weighing, all the reaction materials were placed into a three-dimensional mixing machine to mix for 0.5 hours to 48 hours. After mixing, the reaction materials were taken out and placed into a pressing mold, where they were pressed into a cylindrical block using a cold isostatic press with a pressure of 100 Mpa to 300 MPa. The cylindrical block was placed into a ceramic crucible with a diameter of 280 mm and an inner height of 120 mm, and the ceramic crucible was then placed into the insulation cylinder.

The concentricity between the ceramic crucible and the insulation cylinder was adjusted, and an upper end surface of the ceramic crucible was adjusted to be level with a lower end surface of a middle insulation component. The concentricity between the ceramic crucible and a weighing component, and the concentricity between an upper sealing cover and the weighing component were adjusted in turn, and the sealing between the upper sealing cover and the insulation cylinder was ensured. Further, an observation component and laser shaping and collimating lenses were assembled.

A flowing protective gas Nitrogen (N₂) or a mixture of N₂ and Oxygen (O₂), and cooling water were introduced, in which the oxygen content accounts for 0.1% to 10% of the volume of the flowing gas, and a flow rate of the flowing gas is in a range of 3 mL/min to 30 L/min.

Parameters for growing a crystal were set: the crystal diameter was set to 157 mm, the shoulder length was set to be in a range of 30 mm to 45 mm, the constant diameter length was set to 60 mm, the tailing length was set to be in a range of 20 mm to 40 mm, the heating time was set to be in a range of 3 hours to 24 hours, the rotational speed was set to be in a range of 2 rpm to 10 rpm, the lifting speed was set to be in a range of 1 mm/h to 4 mm/h, the cooling time was set to be in a range of 3 hours to 60 hours, and the proportional-integral-derivative (PID) value was set to 0.5.

An LT seed crystal was attached to the lifting assembly, the lifting assembly was connected to the weighing component, and the concentricity between the seed crystal and the upper sealing cover was adjusted. During a heating process, the seed crystal was slowly lowered for preheating to prevent cracking, while a distance between the seed crystal and a liquid surface of a melt was maintained to be in a range of 5 mm to 15 mm at all times. A transferring component was put from the side of the observation component, the transferring component and an outlet of a mixing component were connected tightly, and supplementary material was prepared in the mixing component. When the raw material was partially melted, the seed crystal was slowly lowered to contact with the melt and the temperature was adjusted. During a temperature adjustment process, the seed crystal was lowered by 2 mm to ensure that the seed crystal and the melt were fully fused with a complete interface, thereby reducing the risk of crystal cracking at the seed crystal junction during the subsequent cooling process. After the temperature was suitable, an automatic control program was started to enter an automatic growth mode.

During the automatic growth mode, temperature information related to the raw material or the cavity was obtained using a temperature-measuring assembly. Based on the obtained temperature information related to the raw material or the cavity, a control assembly outputs a control signal to control at least one of an operating power, a shape of a laser beam, or a size of the laser beam of the laser heating assembly, so as to make a temperature gradient of crystal growth (i.e., a first temperature gradient) in line with or substantially in line with a preset temperature gradient, so as to realize real-time adjustment of the temperature gradient during a crystal growth process. For example, when the first temperature gradient is lower than a preset temperature gradient, the control assembly controls to increase the operating power of laser-emitting units corresponding to an outer sub-ring-like zone, and/or decrease the operating power of laser-emitting units corresponding to an inner sub-ring-like zone, and/or adjust laser shaping and collimating lenses corresponding to the outer sub-ring-like zone to make the size of the corresponding laser beam smaller or adjacent laser beams at least partially overlap, and/or adjust laser shaping and collimating lenses corresponding to the inner sub-ring-like zone to increase the size of corresponding laser beam or reduce an overlapping region between adjacent laser beams, thereby increasing the first temperature gradient so that the first temperature gradient is in line with or substantially in line with the preset temperature gradient. As another example, when the first temperature gradient is higher than the preset temperature gradient, the control assembly controls to decrease the operating power of the laser-emitting units corresponding to the outer sub-ring-like zone, and/or increase the operating power of the laser-emitting units corresponding to the inner sub-ring-like zone, and/or adjust the laser shaping and collimating lenses corresponding to the outer sub-ring-like zone to increase the size of corresponding laser beam or reduce an overlapping region between adjacent laser beams, and/or adjust the laser shaping and collimating lenses corresponding to the inner sub-ring-like zone to make the size of corresponding laser beam smaller or adjacent laser beams at least partially overlap, thereby reducing the first temperature gradient so that the first temperature gradient is in line with or substantially in line with the preset temperature gradient.

Through process steps such as necking, shoulder growth, initiation of automatic feeding, constant diameter growth, tailing growth, cooling, and increasing the oxygen ratio, the crystal growth is completed after 3 days to 5 days.

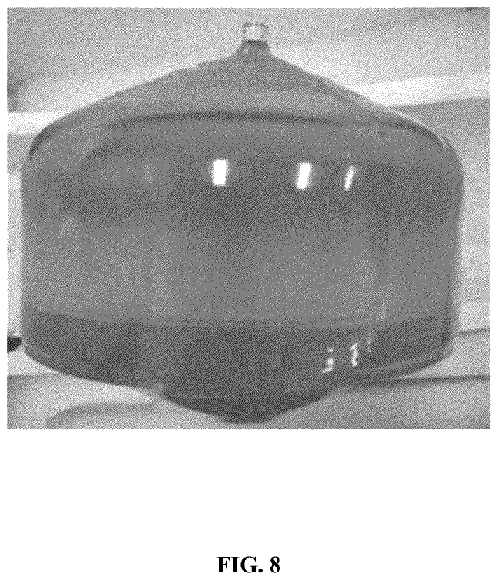

As shown in FIG. 8, the grown crystal is light yellow in color, and its shape matches the preset design. According to the inspection, the crystal has a diameter of 157 mm, a constant diameter length of 60 mm, a smooth surface, and no visible specks or inclusions inside.

### Embodiment 2: Growth of a Cerium-doped Lutetium-Yttrium Oxyorthosilicate(Ce:LYSO) Crystal

Installing steps of a crystal preparation device were performed.

In step 1, a level of a tray assembly was adjusted, and the level is required to be less than 0.1 mm/m.

In step 2, a distance between a lower end surface of a cavity and a bottom plate was adjusted to be no less than 100 mm.

In step 3, a concentricity between the cavity and a lifting assembly was adjusted to be less than 3 mm.

In step 4, raw material required for growing the Ce:LYSO crystal was loaded into the cavity.

In step 5, an insulation cylinder and an upper sealing cover were installed.

In step 6, a furnace cover was installed.

In step 7, laser emitters were installed on the furnace cover. Laser shaping and collimating lenses were installed on an upper end surface of a laser input window and a laser aperture size and relative position were confirmed. A total of 6 laser emitters and 6 corresponding laser shaping and collimating lenses were installed. Among the 6 laser emitters, 6 laser emitters formed a ring-like shape. The radius of the ring-like shape was in a range of 160 mm to 180 mm.

In step 8, a lifting assembly was installed.

Reaction materials required for growing the Ce:LYSO crystal include lutetium oxide, yttrium oxide, silicon oxide, and cerium oxide, the purity of each of which is greater than or equal to 99.999%, and all of which are high-temperature roasted at 1200° C. for 5 hours and then cooled to room temperature. The molar ratios of the reaction materials were calculated based on the following reaction equation:

(1−x−y)Lu₂O₃+yY₂O₃+SiO₂+2×CeO₂→Lu_{2(1-x-y)}Y_{2y}Ce₂ₓSiO₅+x/2O₂←,

where x=0.10%, y=5%-35%, Silicon dioxide (SiO₂) is used in excess by 0.1% to 5% of its theoretical weight, while the other reaction materials were weighed according to their stoichiometric ratios as defined in the chemical equation.

After weighing, all the reaction materials were placed into a three-dimensional mixing machine to mix for 0.5 hours to 48 hours. After mixing, the reaction materials were taken out and placed into a pressing mold, where they were pressed into a cylindrical block using a cold isostatic press with a pressure of 100 MPa to 300 MPa. The cylindrical block was placed into an iridium crucible with a diameter of 220 mm and an internal height of 120 mm, and the iridium crucible was then placed in the insulation cylinder.

The concentricity between the iridium crucible and the insulation cylinder was adjusted, and an upper end surface of the iridium crucible was adjusted to be level with a lower end surface of a middle insulation component. The concentricity between the iridium crucible and a weighing component, and the concentricity between an upper sealing cover and the weighing component were adjusted in turn, and the sealing between the upper sealing cover and the insulation cylinder was ensured. Further, an observation component and laser shaping and collimating lenses were assembled.

A flowing protective gas N₂ or a mixture of N₂ and O₂, and cooling water were introduced, in which the oxygen content accounts for 0.1% to 10% of the volume of the flowing gas, and a flow rate of the flowing gas is in a range of 3 mL/min to 30 L/min.

Parameters for growing a crystal were set: the crystal diameter was set to 75 mm, the shoulder length was set to be in a range of 15 mm to 35 mm, the constant diameter length was set to 189 mm, the tailing length was set to be in a range of 20 mm to 40 mm, the heating time was set to be in a range of 3 hours to 24 hours, the rotational speed was set to be in a range of 2 rpm to 10 rpm, the lifting speed was set to be in a range of 1 mm/h to 4 mm/h, the cooling time was set to be in a range of 3 hours to 60 hours, and the PID value was set to 0.02.

A Ce:LYSO seed crystal was attached to the lifting assembly, and the lifting assembly was connected to the weighing component, and the concentricity between the seed crystal and the upper sealing cover was adjusted. During a heating process, the seed crystal was slowly lowered for preheating to prevent cracking, while a distance between the seed crystal and a liquid surface of a melt was maintained to be in a range of 5 mm to 15 mm at all times. A transferring component was put from the side of the observation component, the transferring component and an outlet of a mixing component were connected tightly, and supplementary material was prepared in the mixing component. When the raw material was partially melted, the seed crystal was slowly lowered to contact with the melt and the temperature was adjusted. During a temperature adjustment process, the seed crystal was lowered by 2 mm to ensure that the seed crystal and the melt were fully fused with a complete interface, thereby reducing the risk of crystal cracking at the seed crystal junction during the subsequent cooling process. After the temperature was suitable, an automatic control program was started to enter an automatic growth mode.

During the automatic growth mode, temperature information related to the raw material or the cavity was obtained using a temperature-measuring assembly. Based on the obtained temperature information related to the raw material or the cavity, a control assembly is configured to output a control signal to control at least one of an operating power of the laser heating assembly, a shape of a laser beam, or a size of the laser beam of the laser heating assembly, so as to make a temperature gradient of crystal growth (i.e., a first temperature gradient) in line with or substantially in line with a preset temperature gradient, so as to realize real-time adjustment of the temperature gradient during a crystal growth process. For example, when the first temperature gradient is lower than a preset temperature gradient, the control assembly controls to increase the operating power of laser-emitting units corresponding to an outer sub-ring-like zone, and/or decrease the operating power of laser-emitting units corresponding to an inner sub-ring-like zone, and/or adjust laser shaping and collimating lenses corresponding to the outer sub-ring-like zone to make the size of the corresponding laser beam smaller or adjacent laser beams at least partially overlap, and/or adjust laser shaping and collimating lenses corresponding to the inner sub-ring-like zone to increase the size of corresponding laser beam or reduce an overlapping region between adjacent laser beams, thereby increasing the first temperature gradient so that the first temperature gradient is in line with or substantially in line with the preset temperature gradient. As another example, when the first temperature gradient is higher than the preset temperature gradient, the control assembly controls to decrease the operating power of the laser-emitting units corresponding to the outer sub-ring-like zone, and/or increase the operating power of the laser-emitting units corresponding to the inner sub-ring-like zone, and/or adjust the laser shaping and collimating lenses corresponding to the outer sub-ring-like zone to increase the size of corresponding laser beam or reduce an overlapping region between adjacent laser beams, and/or adjust the laser shaping and collimating lenses corresponding to the inner sub-ring-like zone to make the size of corresponding laser beam smaller or adjacent laser beams at least partially overlap, thereby reducing the first temperature gradient so that the first temperature gradient is in line with or substantially in line with the preset temperature gradient.

Through process steps such as necking, shoulder growth, initiation of automatic feeding, constant diameter growth, tailing growth, cooling, and increasing the oxygen ratio, the crystal growth is completed after 10 days to 15 days.

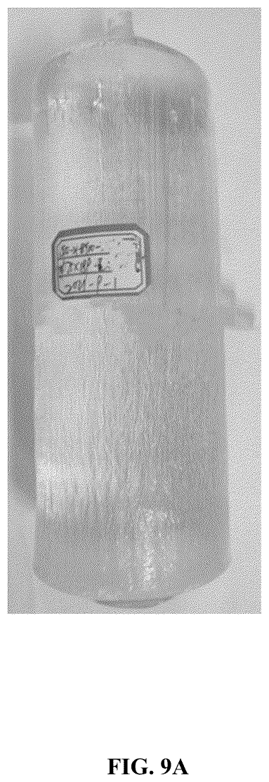

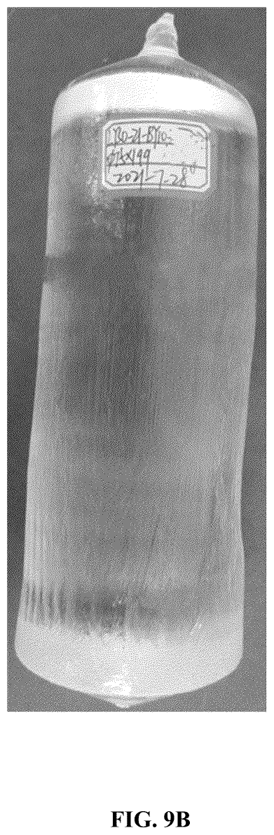

As shown in FIG. 9A and FIG. 9B, the grown crystal is colorless and transparent, with a shape consistent with the preset design. According to the inspection, the crystal has a diameter of 75 mm and a constant diameter length in a range of 189 mm to 199 mm. The crystal surface exhibits slight re-melting striations, and there are no visible specks or inclusions inside the crystal.

Beneficial effects of the embodiments of the present disclosure include the followings. (1) Using the laser heating assembly to heat the raw material can make the raw material located between the ring-like heating zone and the center of the cavity melt to form the raw material melt to grow the crystal, and the raw material located away from the center of the cavity (i.e., near the side wall of the cavity) does not melt, which not only improves the utilization rate of the heat, but also avoids contamination of raw material due to the volatilization of the cavity from the high temperature. (2) Using the laser heating assembly to heat the raw material allows the material of the cavity to be no longer limited to metals such as copper, iron, or stainless steel, which can reduce the cost of the cavity and, in turn, further lower the overall cost of crystal preparation. (3) The cavity includes a cooling structure configured to introduce the cooling medium to reduce the temperature of the cavity, so as to avoid contamination of raw material due to the volatilization of the cavity from the high temperature, and further ensure the quality of the grown crystals. (4) During the crystal growth process, the temperature gradient of the crystal growth can be adjusted in real-time by adjusting the heating parameter of the laser heating assembly, facilitating the automatic growth of the crystal. (5) During the crystal growth process, based on the temperature information related to the raw material or the cavity, the heating parameter of the laser heating assembly can be adjusted in real-time, facilitating the automatic growth of the crystal. It should be noted that the beneficial effects that may be produced by different embodiments are different, and the beneficial effects that may be produced in different embodiments may be any one or a combination of any one or a combination of any of the foregoing, or any other beneficial effect that may be obtained.

The basic concepts have been described above, and it is apparent to those skilled in the art that the foregoing detailed disclosure serves only as an example and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the present disclosure, such as “one embodiment,” “an embodiment,” and/or “some embodiments” means a feature, structure, or characteristic associated with at least one embodiment of the present disclosure. Accordingly, it should be emphasized and noted that two or more references in the present disclosure, at different locations, to “one embodiment” “an embodiment” or “an alternative embodiment” in different places in the present disclosure do not necessarily refer to the same embodiment. In addition, certain features, structures, or characteristics of one or more embodiments of the present disclosure may be suitably combined.

Similarly, it should be noted that in order to simplify the presentation of the present disclosure, and thereby aid in the understanding of one or more embodiments of the invention, the foregoing descriptions of embodiments of the present disclosure sometimes combine a variety of features into a single embodiment, accompanying drawings, or descriptions thereof. However, this method of disclosure does not imply that the objects of the present disclosure require more features than those mentioned in the claims. Rather, claimed subject matter may lie in less than all features of a single foregoing disclosed embodiment.

Some embodiments use numbers to describe the number of components, attributes, and it should be understood that such numbers used in the description of the embodiments are modified in some examples by the modifiers “about,” “approximately,” or “substantially”. Unless otherwise noted, the terms “about,” “approximately,” or “substantially” indicate that a ±20% variation in the stated number is allowed. Correspondingly, in some embodiments, the numerical parameters used in the specification and claims are approximations, which can change depending on the desired characteristics of individual embodiments. In some embodiments, the numerical parameters should consider the specified number of valid digits and employ general place-keeping. While the numerical domains and parameters used to confirm the breadth of their ranges in some embodiments of this specification are approximations, in specific embodiments, such values are set to be as precise as possible within a feasible range.

For each of the patents, patent applications, patent application disclosures, and other materials cited in the present disclosure, such as articles, books, specification sheets, publications, documents, etc., the entire contents of which are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions, and/or use of terms in the present disclosure shall prevail.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

1. A crystal preparation device, comprising:
a cavity configured to accommodate raw material;
a laser heating assembly configured to heat the raw material; and
a control assembly configured to adjust a heating parameter of the laser heating assembly in real-time during a crystal growth process.

2. The crystal preparation device of claim 1, wherein
the cavity includes an inner cavity body and an outer cavity body, and a cooling structure is formed between the inner cavity body and the outer cavity body; and
the cooling structure includes an inlet, an outlet, and a cooling channel, and a cooling medium flows into the cooling channel through the inlet and flows out through the outlet.

3. The crystal preparation device of claim 1, wherein the laser heating assembly includes at least two laser-emitting units installed on a furnace cover above the cavity.

4. The crystal preparation device of claim 3, wherein the at least two laser-emitting units are arranged along a circumferential direction of the furnace cover.

5. The crystal preparation device of claim 4, wherein the at least two laser-emitting units form at least one ring-like shape along the circumferential direction of the furnace cover.

6. The crystal preparation device of claim 5, wherein a difference between a radius of an outermost ring-like shape of the at least one ring-like shape and a radius of the cavity is in a range of 50 mm to 500 mm.

7. The crystal preparation device of claim 5, wherein a radius of an innermost ring-like shape of the at least one ring-like shape is in a range of 25 mm to 300 mm.

8. The crystal preparation device of claim 5, wherein the at least two laser-emitting units form at least two ring-like shapes along the circumferential direction of the furnace cover; and
a radius difference between adjacent ring-like shapes of the at least two ring-like shapes is in a range of 5 mm to 200 mm.

9. The crystal preparation device of claim 1, wherein the heating parameter of the laser heating assembly includes at least one of an operating power of the laser heating assembly, a shape of a laser beam, or a size of the laser beam.

10. The crystal preparation device of claim 1, wherein the control assembly is configured to adjust a temperature gradient in real-time during the crystal growth process by controlling the heating parameter of the laser heating assembly.

11. The crystal preparation device of claim 1, further comprising:
a temperature-measuring assembly configured to measure temperature information related to the raw material or the cavity.

12. The crystal preparation device of claim 11, wherein the control assembly is configured to adjust the heating parameter of the laser heating assembly in real-time based on the temperature information.

13. The crystal preparation device of claim 12, wherein the control assembly is configured to:
perform simulation modeling based on the temperature information; and
adjust the heating parameter of the laser heating assembly in real-time based on a simulation result.

14. The crystal preparation device of claim 1, further comprising:
a feeding assembly configured to feed material in real-time during the crystal growth process.

15. A crystal preparation method, comprising:
placing raw material in a cavity;
heating the raw material by a laser heating assembly to melt a portion of the raw material into a raw material melt; and
performing a crystal growth process based on the raw material melt, wherein a heating parameter of the laser heating assembly is adjusted in real-time during the crystal growth process.

16-17. (canceled)

18. The crystal preparation method of claim 15, wherein
the laser heating assembly form a temperature gradient required for crystal growth during a crystal growth process;
the temperature gradient includes a radial temperature gradient, and the radial temperature gradient includes a first temperature gradient and a second temperature gradient, wherein:
the first temperature gradient is a temperature gradient along a direction from ring-like heating zone formed by the laser heating assembly to a crystal growth center point, the first temperature gradient being a negative temperature gradient; and
the second temperature gradient is a temperature gradient along a direction from the ring-like heating zone to an inner wall of the cavity, the second temperature gradient being a negative temperature gradient.

19-20. (canceled)

21. The crystal preparation device of claim 2, wherein the inner cavity body and the outer cavity body are detachably connected to the crystal preparation device.

22. The crystal preparation device of claim 1, wherein a material of the cavity includes copper, iron, or stainless steel.

23. The crystal preparation device of claim 1, further comprising:
a liquid level sensor configured to measure liquid surface position information of a melt in the cavity.

24. The crystal preparation device of claim 23, wherein the control assembly is configured to control the cavity to move based on the liquid surface position information to maintain a constant distance between the laser heating assembly and a liquid surface of the melt.
